(19) United States
(12) Patent Application Publication
(10) Pub. No.: US 2024/0313059 A1
(43) Pub. Date: Sep. 19, 2024

(54) NITRIDE SEMICONDUCTOR DEVICE AND NITRIDE SEMICONDUCTOR MODULE

(71) Applicant: ROHM CO., LTD., Kyoto-shi (JP)

(72) Inventor: Tsuyoshi TACHI, Kyoto-shi (JP)

(73) Assignee: ROHM CO., LTD., Kyoto-shi (JP)

(21) Appl. No.: 18/602,050

(22) Filed: Mar. 12, 2024

(30) Foreign Application Priority Data
Mar. 16, 2023 (JP) 2023-041956

(51) Int. Cl. H01L 29/20; H01L 27/06; H01L 29/417; H01L 29/66; H01L 29/778

(52) U.S. Cl. CPC H01L 29/2003; H01L 27/0629; H01L 29/41733; H01L 29/66742; H01L 29/7786

(57) ABSTRACT

The present disclosure provides a nitride semiconductor device. The nitride semiconductor device includes: a switching element formed of a nitride semiconductor; a source pad electrically connected to a source electrode of the switching element; a drain pad electrically connected to a drain electrode of the switching element; a gate pad electrically connected to a gate electrode of the switching element; a capacitive element electrically connected to the source electrode of the switching element; a first pad electrically connected to the capacitive element; a resistive element electrically connected to the first pad; and a second pad electrically connected to the resistive element.

### CROSS-REFERENCE TO RELATED APPLICATION

This application is based upon and claims the benefit of priority from Japanese Patent Application No. 2023-041956, filed on Mar. 16, 2023, the entire contents of which are incorporated herein by reference.

### TECHNICAL FIELD

The present disclosure relates to a nitride semiconductor device and a nitride semiconductor module.

### BACKGROUND

Currently, the commercialization of high electron mobility transistors (HEMTs) using nitride semiconductors such as gallium nitride (GaN) is in progress. Patent Document 1 describes an example of a HEMT structure using a nitride semiconductor.

### PRIOR ART DOCUMENT

### Patent Publication

[Patent document 1] Japan Patent Publication No. 2017-73506

### BRIEF DESCRIPTION OF THE DRAWINGS

FIG. 1 is a schematic plan view of an exemplary nitride semiconductor device according to a first embodiment.

FIG. 2 is a schematic cross-sectional view taken along line F2-F2 in FIG. 1.

FIG. 3 is a partially enlarged view of the nitride semiconductor device in F3 region of FIG. 1.

FIG. 4 is a partially enlarged view of the nitride semiconductor device in F4 region of FIG. 3.

FIG. 5 is a schematic cross-sectional view taken along line F5-F5 in FIG. 4.

FIG. 6 is a schematic cross-sectional view taken along line F6-F6 in FIG. 4.

FIG. 7 is a schematic cross-sectional view taken along line F7-F7 in FIG. 1.

FIG. 8 is a schematic cross-sectional view of a first structure example of a resistive element.

FIG. 9 is a schematic cross-sectional view of a second structure example of a resistive element.

FIG. 10 is a schematic plan view of a nitride semiconductor module including the nitride semiconductor device of FIG. 1 wire mounted according to a first mounting example.

FIG. 11 is an equivalent circuit diagram of a switching element with an RC snubber circuit provided by the nitride semiconductor module of FIG. 10.

FIG. 12 is a schematic plan view of a nitride semiconductor module including the nitride semiconductor device of FIG. 1 wire mounted according to a second mounting example.

FIG. 13 is an equivalent circuit diagram of a switching element with a C snubber circuit provided by the nitride semiconductor module of FIG. 12.

FIG. 14 is a partial schematic cross-sectional view of an exemplary nitride semiconductor device according to a second embodiment.

FIG. 15 is a schematic plan view of a nitride semiconductor module including the nitride semiconductor device of FIG. 1 flip-chip mounted according to a third mounting example.

FIG. 16 is a schematic plan view of a nitride semiconductor module including the nitride semiconductor device of FIG. 1 flip-chip mounted according to a fourth mounting example.

FIG. 17 is a schematic plan view of a nitride semiconductor device of a modified example.

### DETAILED DESCRIPTION OF THE EMBODIMENTS

Hereinafter, various embodiments of the nitride semiconductor device and nitride semiconductor module of the present disclosure will be described with reference to the accompanying drawings. In addition, in order to make the description simple and clear, the components shown in the drawings are not necessarily drawn at a fixed reduced scale. Further, in order to facilitate understanding, hatching may be omitted in cross-sectional views. Moreover, the accompanying drawings merely illustrate embodiments of the present disclosure and should not be construed as limiting the present disclosure.

The following detailed description includes devices, systems and methods that embody the exemplary implementations of the present disclosure. The detailed description is intended to be illustrative only, and is not intended to limit the embodiments of the present disclosure or the application and use of such embodiments.

### First Embodiment

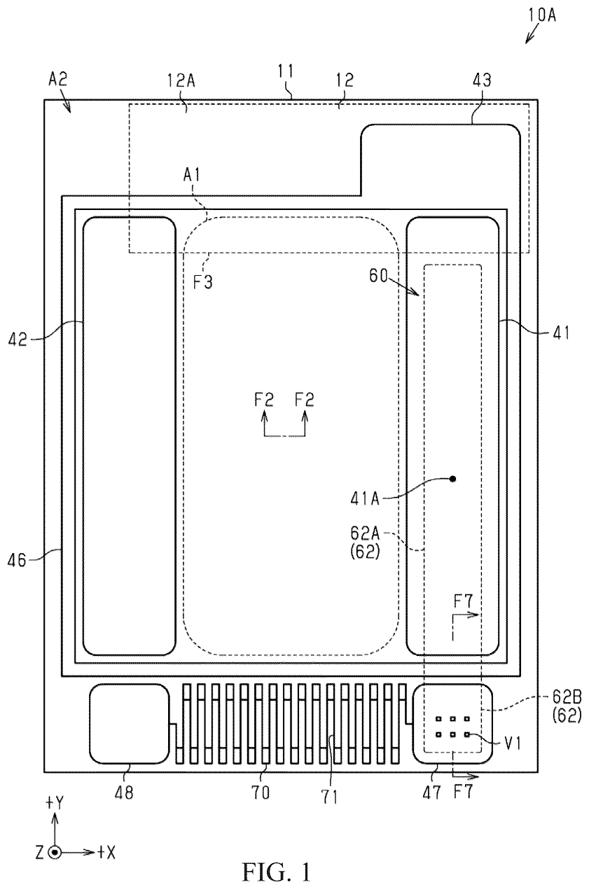

Hereinafter, a nitride semiconductor device 10A and a nitride semiconductor module 100 according to a first embodiment will be described with reference to FIGS. 1 to 13.

### [1. General Structure of Nitride Semiconductor Device]

FIG. 1 shows a schematic plan view structure of the nitride semiconductor device 10A.

In addition, the term “plan view” used in this disclosure refers to viewing the nitride semiconductor device 10A and its related structures in the Z-axis direction of the mutually orthogonal XYZ axes shown in FIG. 1. In addition, in this disclosure, the Y-axis direction corresponds to the “first direction” and the X-axis direction corresponds to the “second direction” orthogonal to the first direction in a plan view. Hereinafter, for the convenience of explanation, in the nitride semiconductor device 10A shown in FIG. 1, the +Z direction is defined as upward, the −Z direction is defined as downward, the +X direction is defined as for the right, and the −X direction is defined as for the left.

As shown in FIG. 1, the nitride semiconductor device 10A includes: a semiconductor substrate 11; a transistor T serving as a switching element formed on the semiconductor substrate 11 (not shown in FIG. 1); and an insulating layer 12 covering the transistor T.

As the semiconductor substrate 11, for example, a silicon (Si) substrate can be used. Alternatively, a silicon carbide (SiC) substrate, a gallium nitride (GaN) substrate, or a sapphire substrate may be used instead of the Si substrate. The thickness of the semiconductor substrate 11 can be, for example, between about 200 μm and about 1,500 μm. In addition, in the following description, “thickness” refers to the dimension along the Z-axis direction unless otherwise stated clearly.

The insulating layer 12 may be made of any one of the material including silicon nitride (SiN), silicon dioxide (SiO₂), silicon oxynitride (SiON), aluminum oxide (Al₂O₃), AlN, and aluminum oxynitride (AlON), for example. In one example, the insulating layer 12 is formed of a material including SiN.

The nitride semiconductor device 10A includes an active region A1 and a peripheral region A2 surrounding the active region A1 in a plan view. In the example of FIG. 1, the active region A1 is located in the central portion of the semiconductor substrate 11 in a plan view, and the peripheral region A2 is located in a frame shape on the outer peripheral side of the semiconductor substrate 11. The active region A1 is a region where the transistor T is formed, and the peripheral region A2 is a region where the transistor T is not formed.

### [2. Transistor Structure]

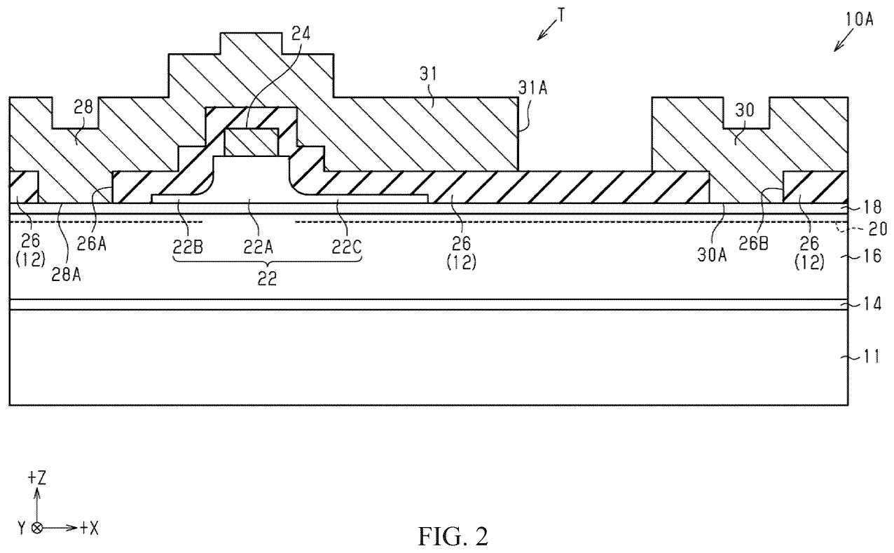

FIG. 2 is a partial schematic cross-sectional view of the nitride semiconductor device 10A taken along line F2-F2 in FIG. 1, showing an example of the schematic cross-sectional structure of the transistor T. In addition, in FIG. 2, a partial illustration of the insulating layer 12 covering the upper side of the transistor T is omitted.

As shown in FIG. 2, the transistor T is a high electron mobility transistor (HEMT) using a nitride semiconductor. The transistor T includes a buffer layer 14 formed on the semiconductor substrate 11, an electron transport layer 16 formed on the buffer layer 14, and an electron supply layer 18 formed on the electron transport layer 16.

The buffer layer 14 may be made of any material capable of suppressing warpage or deterioration of the wafer due to a thermal expansion coefficient mismatch between the semiconductor substrate 11 and the electron transport layer 16. The buffer layer 14 includes one or more nitride semiconductor layers made of a nitride semiconductor. The buffer layer 14 may include, for example, at least one of an aluminum nitride (AlN) layer, an aluminum gallium nitride (AlGaN) layer, and a graded AlGaN layer having different aluminum (Al) compositions. For example, the buffer layer 14 may be composed of a single AlN film, a single AlGaN film, a film having an AlGaN/GaN superlattice structure, a film having an AlN/AlGaN superlattice structure, a film having an AlN/GaN superlattice structure or the like.

In one example, the buffer layer 14 includes an AlN layer (i.e., the first buffer layer) formed on the semiconductor substrate 11 and an AlGaN layer (i.e., the second buffer layer) formed on the AlN layer (the first buffer layer). The first buffer layer may be, for example, an AlN layer with a thickness of 200 nm, and the second buffer layer may be, for example, a graded AlGaN layer with a thickness of 300 nm. In order to suppress leakage current in the buffer layer 14, impurities can be introduced into a portion of the buffer layer 14 to make the buffer layer 14 semi-insulating except for the surface layer region. In this case, the impurity is carbon (C) or iron (Fe), for example. The impurity concentration can be set to 4×10¹⁶ cm⁻³ or more, for example.

The electron transport layer 16 is composed of a nitride semiconductor. The electron transport layer 16 may be a GaN layer, for example. The thickness of the electron transport layer 16 can be, for example, between about 0.5 μm and about 2 μm. In order to suppress the leakage current in the electron transport layer 16, impurities can be introduced into a portion of the electron transport layer 16 to make the electron transport layer 16 semi-insulating except for the surface layer region. In this case, the impurity is C, for example. The impurity concentration can be set to 4×10¹⁶ cm⁻³ or more, for example.

The electron transport layer 16 may include multiple GaN layers with different impurity concentrations. In one example, the electron transport layer 16 may include a C-doped GaN layer and an undoped GaN layer. In this case, the C-doped GaN layer is formed on the buffer layer 14. The thickness of the C-doped GaN layer can be, for example, between about 0.3 μm and about 2 μm. The C concentration in the C-doped GaN layer can be, for example, between about 5×10¹⁷ cm⁻³ and about 9×10¹⁹ cm⁻³. The undoped GaN layer is formed on the C-doped GaN layer. The thickness of the undoped GaN layer can be, for example, between about 0.05 μm and about 0.4 μm. The undoped GaN layer is in contact with the electron supply layer 18. In one example, the electron transport layer 16 includes a C-doped GaN layer with a thickness of 0.4 μm and an undoped GaN layer with a thickness of 0.4 μm. The C concentration in the C-doped GaN layer is approximately 2×10¹⁹ cm⁻³.

The electron supply layer 18 is composed of a nitride semiconductor having a larger band gap than the electron transport layer 16. The electron supply layer 18 may be an AlGaN layer, for example. In nitride semiconductors, the higher the A1 composition, the larger the band gap. Therefore, the AlGaN layer, which is the electron supply layer 18, has a larger band gap than the GaN layer, which is the electron transport layer 16. In one example, the electron supply layer 18 is composed of AlₓGa₁₋ₓN. Here, x is, for example, 0<x<0.4, and more preferably, 0.1<x<0.3. The thickness of the electron supply layer 18 can be, for example, between about 5 nm and about 20 nm.

The electron transport layer 16 and the electron supply layer 18 have different lattice constants in the main body region. Therefore, the electron transport layer 16 and the electron supply layer 18 form a lattice mismatched heterojunction. Due to the spontaneous polarization of the electron transport layer 16 and the electron supply layer 18 and the piezoelectric polarization caused by the compressive stress exerted on the heterojunction portion of the electron transport layer 16, the energy level of the conduction band of the electron transport layer 16 near the heterojunction interface between the electron transport layer 16 and the electron supply layer 18 is lower than the Fermi level. Therefore, at a position close to the heterojunction interface between the electron transport layer 16 and the electron supply layer 18 (for example, a distance of about several nm from the interface), the two-dimensional electron gas (2DEG: Two-dimensional electron gas) 20 diffuses in the electron transport layer 16.

The transistor T includes a gate layer 22 formed on the electron supply layer 18, a gate electrode 24 formed on the gate layer 22, the electron supply layer 18, the gate layer 22, and an insulating layer 26 covering the gate electrode 24. The gate electrode 24 is formed on a portion of the gate layer 22. The insulating layer 26 includes a source opening 26A and a drain opening 26B that are spaced apart from the gate layer 22 on both sides of the gate layer 22 in the X-axis direction. That is, the source opening 26A and the drain opening 26B are spaced apart from each other in the X-axis direction.

The gate layer 22 is located between the source opening 26A and the drain opening 26B. The gate layer 22 is disposed closer to the source opening 26A than the drain opening 26B in the X-axis direction. That is, the distance between the gate layer 22 and the drain opening 26B in the X-axis direction is longer than the distance between the gate layer 22 and the source opening 26A in the X-axis direction.

The gate layer 22 is composed of a nitride semiconductor. For example, the gate layer 22 may be composed of any material having a smaller band gap than the AlGaN layer, i.e., the electron supply layer 18. In addition, in the first embodiment, the gate layer 22 is composed of a nitride semiconductor containing acceptor-type impurities. In one example, the gate layer 22 is a GaN layer doped with acceptor-type impurities (p-type GaN layer). The acceptor-type impurity may include at least one of zinc (Zn), magnesium (Mg), and C. The maximum concentration of acceptor-type impurities in the gate layer 22 is, for example, between about 1×10¹⁸ cm⁻³ and about 1×10²⁰ cm⁻³.

In addition, in this disclosure, the nitride semiconductor constituting the electron transport layer 16 corresponds to the first nitride semiconductor, and the nitride semiconductor constituting the electron supply layer 18 corresponds to the second nitride semiconductor. Furthermore, the nitride semiconductor constituting the gate layer 22 corresponds to the third nitride semiconductor.

By making the gate layer 22 contain acceptor-type impurities, the energy levels of the electron transport layer 16 and the electron supply layer 18 are raised. As a result, in the area directly below the gate layer 22, the energy level of the conduction band of the electron transport layer 16 near the heterojunction interface between the electron transport layer 16 and the electron supply layer 18 is almost the same as, or greater than, the Fermi level. Therefore, under zero bias voltage in which no voltage is applied to the gate electrode 24, 2DEG 20 is not formed in the electron transport layer 16 in the region directly below the gate layer 22. On the other hand, 2DEG 20 is formed in the electron transport layer 16 in the region other than the region directly below the gate layer 22.

In this way, due to the presence of the gate layer 22 doped with acceptor-type impurities, the channel of the 2DEG 20 disappears in the region directly below the gate layer 22. As a result, the normally-off operation of the transistor T is realized. When an appropriate turn-on voltage is applied to the gate electrode 24, the electron transport layer 16 in the region directly below the gate electrode 24 forms a channel of the 2DEG 20, so that the source-drain conduction occurs.

The shape of the gate layer 22 is not particularly limited. In the example of FIG. 2, the gate layer 22 has a step (step difference) structure. For example, the gate layer 22 includes a gate layer body portion 22A, a first extension portion 22B extending from the first side surface (the left side surface in FIG. 2) of the gate layer body portion 22A toward the source opening 26A, and a second extension portion 22C extending from the second side surface (the right side surface in FIG. 2) of the gate layer body portion 22A toward the drain opening 26B. The gate electrode 24 is located on the gate layer body portion 22A. The gate layer body portion 22A may have any cross-sectional shape such as a rectangular shape, a trapezoidal shape, or a ridge shape in the XZ plane. The thickness of the gate layer body portion 22A, i.e. the distance from the upper surface of the gate layer body portion 22A to the lower surface of the gate layer body portion 22A (the lower surface of the gate layer 22 that is in contact with the electron supply layer 18) can be set to be between about 80 nm and about 150 nm.

The first extension portion 22B extends from the gate layer body portion 22A toward the source opening 26A and is spaced apart from the source opening 26A. The second extension portion 22C extends from the gate layer body portion 22A toward the drain opening 26B and is spaced apart from the drain opening 26B. In the example of FIG. 2, the second extension portion 22C is formed longer than the first extension portion 22B in the X-axis direction. However, the first extension portion 22B and the second extension portion 22C may have the same length. The length of the first extension portion 22B in the X-axis direction can be, for example, between about 0.2 μm and about 0.3 μm. The length of the second extension portion 22C in the X-axis direction can be, for example, between about 0.2 μm and about 1.5 μm.

The gate electrode 24 is composed of one or more metal layers. In one example, the gate electrode 24 is a titanium nitride (TiN) layer. Alternatively, the gate electrode 24 may include a first metal layer formed of a material containing Ti, and a second metal layer laminated on the first metal layer and formed of a material containing TiN. When the gate electrode 24 is made of TiN, for example, the gate electrode 24 and the gate layer 22 form a Schottky junction. The gate electrode 24 is formed in a smaller region than the gate layer body portion 22A in a plan view. However, the gate electrode 24 may be formed in the same region as the gate layer body portion 22A in a plan view. The thickness of the gate electrode 24 can be, for example, between about 50 nm and about 200 nm.

The insulating layer 26 is formed on the electron supply layer 18. The insulating layer 26 is a portion of the insulating layer 12 covering the transistor T. Insulating layer 26 is also referred to a passivation layer. The insulating layer 26 covers the gate layer 22 and the gate electrode 24. The thickness of the insulating layer 26 can be, for example, between about 80 nm and about 150 nm.

The transistor T further includes a source electrode 28 connected to the electron supply layer 18 via the source opening 26A, and a drain electrode 30 connected to the electron supply layer 18 via the drain opening 26B.

The source electrode 28 and the drain electrode 30 are composed of one or more metal layers (for example, Ti, Al, AlCu, TiN, etc.). The source electrode 28 includes a source contact portion 28A that is in contact with the electron supply layer 18 via the source opening 26A, and is in ohmic contact with the 2DEG 20 directly below the source contact portion 28A via the source opening 26A. The drain electrode 30 includes a drain contact portion 30A that is in contact with the electron supply layer 18 via the drain opening 26B, and is in ohmic contact with the 2DEG 20 directly below the drain contact portion 30A via the drain opening 26B.

The transistor T may also include a field plate electrode 31 formed on the insulating layer 26. The field plate electrode 31 extends in a region between the gate layer 22 and the drain electrode 30 and is spaced apart from the drain electrode 30. Therefore, the field plate electrode 31 includes an end portion 31A located between the drain electrode 30 (the drain opening 26B) and the gate layer 22 in a plan view.

The field plate electrode 31 is electrically connected to the source electrode 28. In the example of FIG. 2, the field plate electrode 31 and the source electrode 28 are formed continuously and integrally. In the case of such an integrated electrode, the electrode portion embedded in the source opening 26A or, in addition, the electrode portion located near the source opening 26A can correspond to the source electrode 28. The field plate electrode 31 can correspond to the remaining portion of the integrated electrode except the source electrode 28. The field plate electrode 31 plays a role in alleviating the electric field concentration near the end of the gate layer 22 and the end of the gate electrode 24 under zero bias when the gate voltage is not applied to the gate electrode 24.

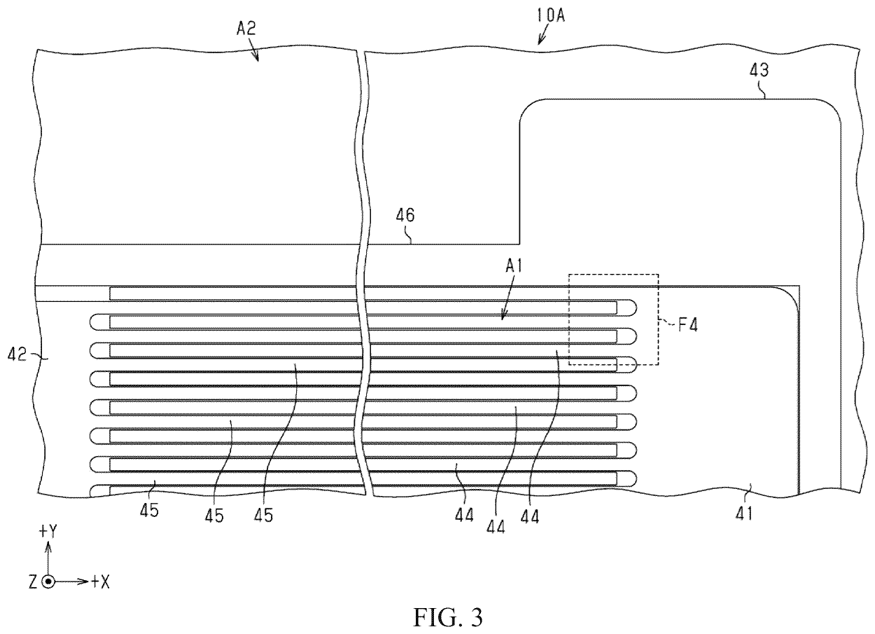

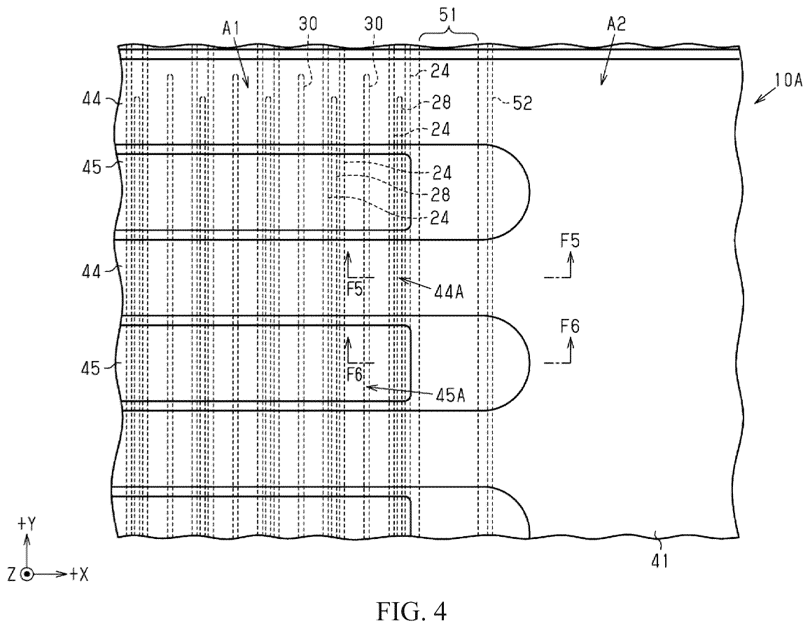

FIG. 3 is a partial enlarged view of the nitride semiconductor device 10A in the F3 region of FIG. 1, and FIG. 4 is a partial enlarged view of the nitride semiconductor device 10A in the F4 region of FIG. 3. In addition, in FIG. 4, the portion of the source electrode 28 embedded in the source opening 26A, the portion of the drain electrode 30 embedded in the drain opening 26B, and the gate electrode 24 are shown in perspective view.

As shown in FIG. 4, the source electrode 28, the drain electrode 30 and the gate electrode 24 extend in a long strip shape in the Y-axis direction. In addition, although illustration is omitted, the gate layer 22 and the field plate electrode 31 also extend in a long strip shape in the Y-axis direction. That is, the transistors T (HEMT) shown in FIG. 2 are formed continuously in the Y-axis direction. Further, a plurality of transistors T (unit transistors) are arranged in an array in the active region A1, one of which is illustrated in FIG. 2. For example, in the active region A1, a plurality of transistors Tl are arranged in an array along each of the X-axis direction and the Y-axis direction. In addition, although not shown in FIG. 4, the end portion of the gate electrode 24 protrudes from the active region A1 into the peripheral region A2.

### [3. Structures of Various Electrode Pads and Various Wirings, and Peripheral Structures]

As shown in FIG. 1, the nitride semiconductor device 10A includes a source pad 41, a drain pad 42 and a gate pad 43 respectively formed on the upper surface 12A of the insulating layer 12. The source pad 41, the drain pad 42 and the gate pad 43 may be made of any conductive material comprising at least one of copper (Cu), aluminum (Al), AlCu alloy, tungsten (W), titanium (Ti) and titanium nitride (TiN), for example.

The source pad 41 is an electrode pad electrically connected to the source electrode 28. In the example of FIG. 1, the source pad 41 is located on the right side (+X direction side) of the active region A1 and is arranged in the peripheral region A2 in alignment with the active region A1. The source pad 41 has a rectangular shape extending in the Y-axis direction in a plan view. The source pad 41 may be formed in almost the same size as the active region A1 along the Y-axis direction.

The drain pad 42 is an electrode pad electrically connected to the drain electrode 30. In the example of FIG. 1, the drain pad 42 is located on the left side (−X direction side) of the active region A1 and is arranged in the peripheral region A2 in alignment with the active region A1. The drain pad 42 has a rectangular shape extending in the Y-axis direction in a plan view. The drain pad 42 may be formed in almost the same size as the active region A1 along the Y-axis direction.

The gate pad 43 is an electrode pad electrically connected to the gate electrode 24. In the example of FIG. 1, the gate pad 43 is located on the upper side (+Y direction side) of the source pad 41, that is, on the upper side of the active region A1, and is arranged in the peripheral region A2 in alignment with the source pad 41.

As shown in FIGS. 1 and 3, the nitride semiconductor device 10A includes a plurality of source wirings 44 extending from the source pad 41, a plurality of drain wirings 45 extending from the drain pad 42, and a gate wiring 46 extending from the gate pad 43. The source wiring 44, the drain wiring 45 and the gate wiring 46 are formed on the upper surface 12A of the insulating layer 12. In addition, in FIG. 1, the source wiring 44 and the drain wiring 45 are not shown.

The source wiring 44 extends in a comb-like shape in the X-axis direction from the source pad 41 toward the drain pad 42. The source wiring 44 is provided across both the peripheral region A2 and the active region A1, and the front end of the source wiring 44 is located in the active region A1. The source wirings 44 are spaced apart at equal intervals in the Y-axis direction. In addition, the source wiring 44 is integrally formed with the source pad 41.

The drain wiring 45 extends in a comb-like shape in the X-axis direction from the drain pad 42 toward the source pad 41. The drain wiring 45 is provided across both the peripheral region A2 and the active region A1, and the front end of the drain wiring 45 is located in the active region A1. The drain wirings 45 are arranged at equal intervals in the Y-axis direction. In addition, the source wirings 44 and the drain wirings 45 are each alternately arranged in the Y-axis direction and spaced apart from each other. In addition, the drain wiring 45 and the drain pad 42 are formed integrally.

As shown in FIG. 1, the gate wiring 46 extends annularly from the gate pad 43 in a plan view. The gate wiring 46 and the gate pad 43 connected to each other are entirely arranged in a frame shape surrounding the active region A1, the source pad 41, and the drain pad 42. In addition, the gate wiring 46 and the gate pad 43 are formed integrally.

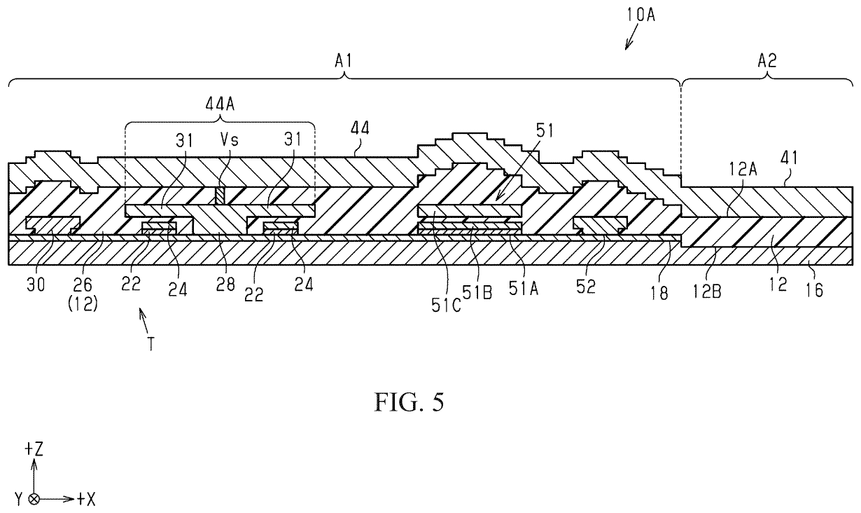

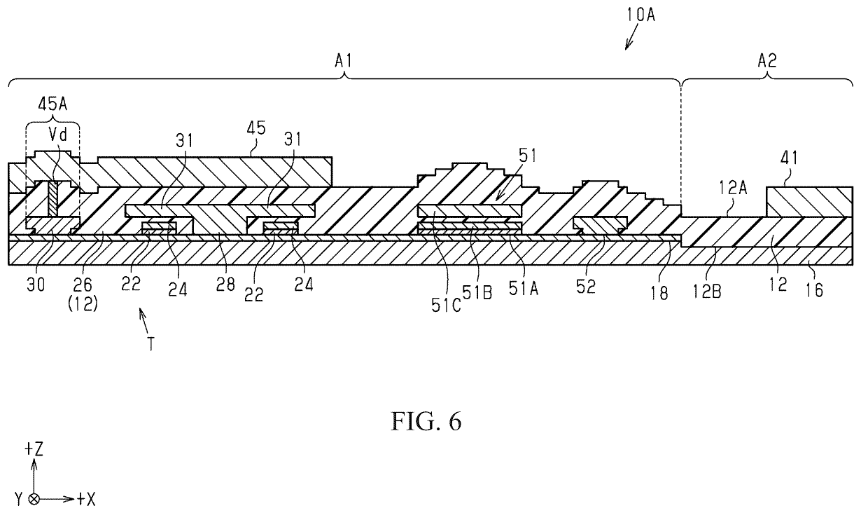

FIG. 5 is a partial schematic cross-sectional view of the nitride semiconductor device 10A taken along line F5-F5 of FIG. 4, and FIG. 6 is a partial schematic cross-sectional view of the nitride semiconductor device 10A taken along line F6-F6 of FIG. 4. In addition, in FIGS. 5 and 6, the cross-sectional structure of the transistor T is simplified compared with the cross-sectional structure of FIG. 2 for the illustration to be understood easily. For example, only the portion of the gate layer 22 directly below the gate electrode 24 is shown in a simplified manner. In addition, the shape of the integrated electrode of the source electrode 28 and the field plate electrode 31 is simplified. In addition, illustration of the semiconductor substrate 11 and the buffer layer 14 is omitted.

As shown in FIGS. 5 and 6, the electron supply layer 18 is not formed in the peripheral region A2. The electron transport layer 16 located in the peripheral region A2 is provided as an outer peripheral portion made of a first nitride semiconductor (for example, GaN) with the upper portion of the electron transport layer 16 removed, and the insulating layer 12 is formed on and in contact with the outer peripheral portion. Since the electron supply layer 18 does not exist on the electron transport layer 16 provided as the outer peripheral portion, 2DEG 20 is not generated at the outer peripheral portion.

As shown in FIGS. 4 and 5, the source wiring 44 includes an overlapping portion 44A that overlaps the source electrode 28 (and the field plate electrode 31 formed integrally therewith) in a plan view. At a position corresponding to the overlapping portion 44A, a via hole Vs is formed in the insulating layer 12 between the source wiring 44 and the source electrode 28 to penetrate the insulating layer 12 and electrically connect the source wiring 44 and the source electrode 28.

As shown in FIGS. 4 and 6, the drain wiring 45 has an overlapping portion 45A that overlaps the drain electrode 30 in a plan view. At a position corresponding to the overlapping portion 45A, a via hole Vd is formed through the insulating layer 12 between the drain wiring 45 and the drain electrode 30 to electrically connect the drain wiring 45 and the drain electrode 30.

In addition, although the illustration is omitted, the gate wiring 46 includes an overlapping portion that overlaps with the end portion of the gate electrode 24 protruding into the peripheral region A2 in a plan view, and is electrically connected to the gate electrode 24 through a via hole penetrating through the insulating layer 12 at a position corresponding to the overlapping portion.

As shown in FIGS. 4 to 6, a square frame-shaped first outer peripheral guard ring 51 and a second outer peripheral guard ring 52 surrounding the central portion of the active region A1 are provided at the outer peripheral portion inside the active region A1.

An example of the first outer peripheral guard ring 51 includes a semiconductor layer 51A provided on and in contact with the electron supply layer 18, a first conductive layer 51B provided on and in contact with the semiconductor layer 51A, and a second conductive layer 51C buried in the insulating layer 12 above the first conductive layer 51B. The semiconductor layer 51A is made of, for example, the same material as the gate layer 22. The first conductive layer 51B is made of, for example, the same material as the gate electrode 24. The second conductive layer 51C is made of, for example, the same material as the source electrode 28 and the drain electrode 30.

The second outer peripheral guard ring 52 is provided on the outer peripheral side of the active region A1 than the first outer peripheral guard ring 51 so as to surround the first outer peripheral guard ring 51. An example of the second outer peripheral guard ring 52 is a conductive layer provided on and in contact with the electron supply layer 18. The second outer peripheral guard ring 52 is made of, for example, the same material as the source electrode 28 and the drain electrode 30.

### [4. Capacitive Element]

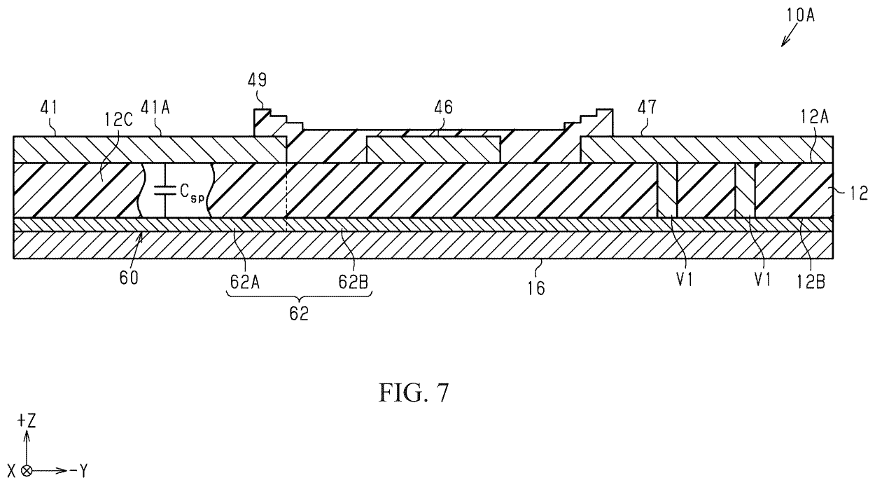

As shown in FIGS. 1 and 7, the nitride semiconductor device 10A includes a capacitive element 60. FIG. 7 is a partial schematic cross-sectional view of the nitride semiconductor device 10A taken along line F7-F7 in FIG. 1.

In the first embodiment shown in the example of FIG. 7, the capacitive element 60 is formed using the insulating layer 12, the source pad 41 formed on the upper surface 12A of the insulating layer 12, and an electrode layer 62 formed on the lower surface 12B of the insulating layer 12. The source pad 41 and the electrode layer 62 are both provided in the peripheral region A2. Therefore, the capacitive element 60 is provided in the peripheral region A2.

The capacitive element 60 includes a first electrode 41A, a second electrode 62A facing the first electrode 41A, and a dielectric layer 12C interposed between the first electrode 41A and the second electrode 62A. The first electrode 41A corresponds to one of the two counter electrodes of the capacitive element 60, and the second electrode 62A corresponds to the other of the two counter electrodes of the capacitive element 60.

The first electrode 41A is formed of at least a portion of the source pad 41 electrically connected to the source electrode 28. The first electrode 41A corresponds to the portion of the source pad 41 that overlaps the electrode layer 62 in a plan view. In other words, the source pad 41 includes a portion that overlaps the electrode layer 62 in a plan view as the first electrode 41A. Therefore, the first electrode 41A has a source potential, and the capacitive element 60 is electrically connected to the source electrode 28.

The second electrode 62A is formed from at least a portion of the electrode layer 62. The electrode layer 62 is provided so as to at least partially overlap the source pad 41 in a plan view. In the example of FIG. 7, a portion of the electrode layer 62 overlaps the source pad 41 in a plan view. The second electrode 62A corresponds to the portion of the electrode layer 62 that overlaps the source pad 41 in a plan view. In other words, the electrode layer 62 includes a portion that overlaps the source pad 41 in a plan view as the second electrode 62A.

As shown in FIG. 1, the second electrode 62A has a rectangular shape in a plan view and extends in the Y-axis direction along the source pad 41. The width of the second electrode 62A in the X-axis direction is narrower than the width of the source pad 41 in the X-axis direction. However, the width of the second electrode 62A may be wider than the width of the source pad 41. In addition, the plan view shape of the second electrode 62A is not necessarily a rectangular shape.

In the example of FIG. 1, a portion of the source pad 41 that overlaps the electrode layer 62 in a plan view is formed as the first electrode 41A. However, the entire source pad 41 may be formed as the first electrode 41A. In such case, by forming the electrode layer 62 to have a size larger than the source pad 41 in a plan view, the second electrode 62A is formed to have the same size as the source pad 41. In addition, although not shown in FIGS. 1 and 7, the source pad 41 is electrically connected to the source electrode 28 through the via hole Vs (referring to FIG. 6) formed in the insulating layer 12 as described above.

The dielectric layer 12C is formed from a portion of the insulating layer 12. Therefore, in the first embodiment, the dielectric layer 12C is formed of the same material as the insulating layer 12 and is located on the same layer as the insulating layer 12. In addition, in FIG. 7, for ease of understanding, the boundary of the second electrode 62A and the boundary of the dielectric layer 12C are shown with dotted lines, but such boundary lines do not definitely exist.

The electrode layer 62 is in contact with the lower surface 12B of the insulating layer 12 and is provided on the outer peripheral portion of the electron transport layer 16 in the peripheral region A2 (a region where 2DEG 20 does not occur). The electrode layer 62 may be made of, for example, any conductive material comprising at least one of copper (Cu), aluminum (Al), aluminum silicon copper (AlSiCu), aluminum copper (AlCu), tungsten (W), titanium (Ti), and titanium nitride (TiN). An example of the material of the electrode layer 62 is the same material as the gate electrode 24, such as TiN. In such case, the electrode layer 62 is formed by patterning simultaneously with the gate electrode 24. Examples of other materials for the electrode layer 62 are the same materials as the source electrode 28 and the drain electrode 30, such as AlCu. In such case, the electrode layer 62 is formed by patterning simultaneously with the source electrode 28 and the drain electrode 30.

The electrode layer 62 includes the connection portion 62B in addition to the second electrode 62A. In the example of FIG. 7, the second electrode 62A and the connecting portion 62B are formed integrally. The connection portion 62B can correspond to a portion of the electrode layer 62 other than the second electrode 62A. That is, the connection portion 62B can correspond to the portion of the electrode layer 62 that does not overlap the source pad 41 in a plan view. The connection portion 62B functions as a wiring layer for electrically connecting the capacitive element 60 and a specific pad (a first pad 47 in FIG. 7) described later.

The capacitive element 60 forms a specific capacitance Cₛₚ between the first electrode 41A and the second electrode 62A based on the following formula (1).

$${C}_{s p} = ε \times ( S / d ) \qquad ( 1 )$$

Here, in formula (1), S is the area of each of the first electrode 41A and the second electrode 62A that face each other, that is, the opposing area. d is the distance between the first electrode 41A and the second electrode 62A, that is, the inter-electrode distance. In the example shown in FIG. 7, the inter-electrode distance d is equal to the thickness of the dielectric layer 12C. ε is the dielectric constant of the dielectric layer 12C interposed between the first electrode 41A and the second electrode 62A. Therefore, the specific capacitance Cₛₚ can be changed by changing at least one of the opposing area S, the inter-electrode distance d, and the dielectric constant ε of the dielectric layer 12C.

As an example, the opposing area S can be set to between about 0.02 mm² and about 0.4 mm². The inter-electrode distance d (that is, the thickness of the dielectric layer 12C) can be, for example, between about 50 nm and about 3,000 nm. The dielectric constant ε of the dielectric layer 12C can be changed by changing the type of the dielectric layer 12C (that is, the material of the insulating layer 12).

### [5. Specific Pad]

As shown in FIG. 1, the nitride semiconductor device 10A includes a first pad 47 and a second pad 48 provided as two specific pads. The first pad 47 and the second pad 48 are provided on the upper surface 12A of the insulating layer 12. The first pad 47 and the second pad 48 may be made of the same conductor material as the source pad 41, the drain pad 42, and the gate pad 43, for example.

The first pad 47 is arranged in the peripheral region A2. In the example of FIG. 1, the first pad 47 is located on the lower side (−Y direction side) of the active region A1 and is arranged in the peripheral region A2 in line with the source pad 41. The gate wiring 46 is located between the first pad 47 and the source pad 41. The first pad 47 may have a square shape in a plan view, for example. However, the first pad 47 may have a rectangular shape, a circular shape, or an elliptical shape other than the square shape. The size of the first pad 47 in a plan view is not particularly limited either.

The second pad 48 is arranged in the peripheral region A2. In the example of FIG. 1, the second pad 48 is located on the lower side (−Y direction side) of the active region A1 and is arranged in the peripheral region A2 in line with the drain pad 42. The gate wiring 46 is located between the second pad 48 and the drain pad 42. The second pad 48 may have a square shape in a plan view, for example. However, the second pad 48 may have a rectangular shape, a circular shape, or an elliptical shape other than the square shape. The size of the second pad 48 in a plan view is not particularly limited either.

When the nitride semiconductor device 10A is provided as a semiconductor chip, the first pad 47 and the second pad 48 are in a potential-free state, that is, an electrically floating state, and are not electrically connected to any electrode pad. The first pad 47 and the second pad 48 are electrically connected to the drain pad 42 as necessary when the nitride semiconductor device 10A is mounted in a nitride semiconductor module described below. That is, the first pad 47 and the second pad 48 are provided for electrical connection with the drain pad 42.

As shown in FIGS. 1 and 7, the first pad 47 is provided at a position overlapping the connection portion 62B, that is, the electrode layer 62 in a plan view. Therefore, the electrode layer 62 is provided across both the source pad 41 and the first pad 47 in a plan view. In the example of FIG. 7, the connection portion 62B extends in the Y-axis direction (−Y direction) from the second electrode 62A, and a portion thereof is located below the first pad 47. In the area where the connection portion 62B and the first pad 47 overlap in a plan view, a via hole V1 is formed penetrating the insulating layer 12 between the connection portion 62B and the first pad 47 to electrically connect the connection portion 62B to the first pad 47. Therefore, the first pad 47 is connected to the electrode layer 62 via the via hole V1. That is, the first pad 47 is connected to the connection portion 62B and the second electrode 62A through the via hole V1. Therefore, for example, when the first pad 47 is electrically connected to the drain pad 42, the second electrode 62A of the capacitive element 60 is set to the drain potential. In addition, in this disclosure, the via hole V1 is an example of the first through conductor.

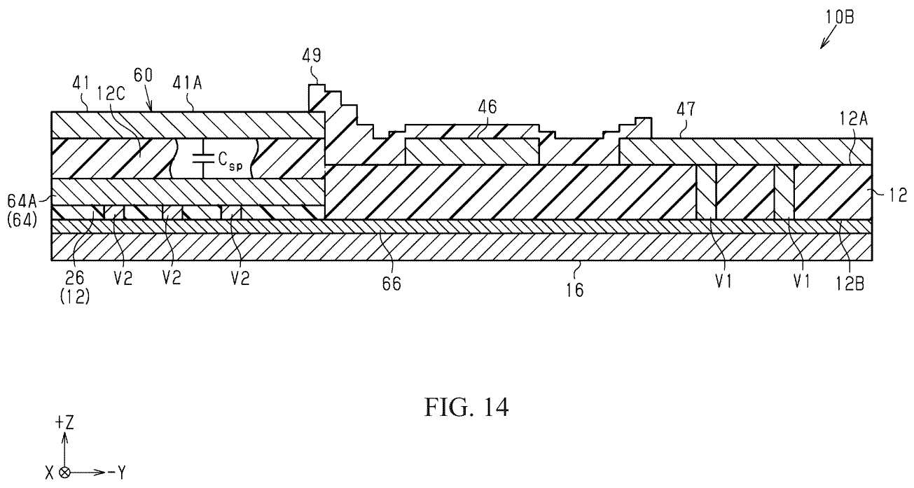

As shown in FIG. 7, the nitride semiconductor device 10A includes a protective film 49 provided on the upper surface 12A of the insulating layer 12. The protective film 49 may be formed to cover a portion of each pad (the source pad 41, the drain pad 42, the gate pad 43, the first pad 47, and the second pad 48) and expose them. In the example of FIG. 7, the protective film 49 also covers the gate wiring 46 located between the source pad 41 and the first pad 47. In addition, in drawings other than FIG. 7 (and FIG. 14 to be described later), the protective film 49 is omitted from the illustration. The protective film 49 may be made of an insulating material such as polyimide.

### [6. Resistive Element]

As shown in FIG. 1, the nitride semiconductor device 10A includes a resistive element 70. The resistive element 70 is electrically connected to the first pad 47 and the second pad 48. The resistive element 70 includes a connection path 71 connected between the first pad 47 and the second pad 48. The connection path 71 is formed in a meandering manner when viewed from above. The structure of the resistive element 70 is not particularly limited. Two structure examples of the resistive element 70 will be described below.

### [6-1. First Structure Example of Resistive Element]

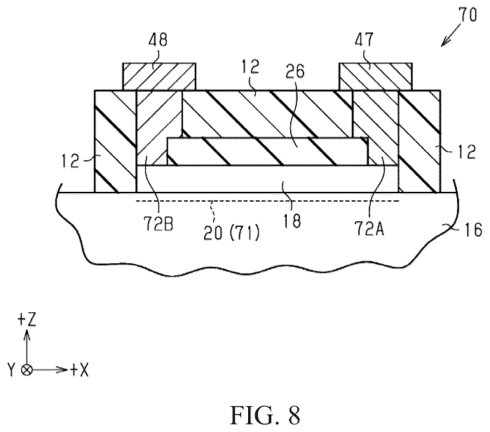

FIG. 8 is a schematic cross-sectional view of the first structure example of the resistive element 70. In the first structure example, the resistive element 70 has a path of the 2DEG 20 generated in the electron transport layer 16 as the connection path 71. For example, in the area where the resistive element 70 is formed, the electron supply layer 18 is formed to be meandering when viewed from above, following the shape shown as the connection path 71 in FIG. 1. As a result, 2DEG 20 (connection path 71) is formed in the electron transport layer 16 directly below the electron supply layer 18 in a meandering way.

The resistive element 70 includes a first terminal 72A and a second terminal 72B electrically connected to both ends of the connection path 71 formed by the 2DEG 20. The first terminal 72A and the second terminal 72B are provided on the electron supply layer 18 through the insulating layer 12 and are in ohmic contact with the 2DEG 20 (connection path 71) directly below the electron supply layer 18. For example, the same metal material as the source electrode 28 and the drain electrode 30 may be used for the first terminal 72A and the second terminal 72B. The first terminal 72A includes an upper end portion exposed from the insulating layer 12, and the first pad 47 is connected to the upper end portion of the first terminal 72A. The second terminal 72B includes an upper end portion exposed from the insulating layer 12, and the second pad 48 is connected to the upper end portion of the second terminal 72B.

In the resistive element 70 of the first structure example, the resistance value R of the connection path 71 is set based on the length and width of the 2DEG 20 formed as the connection path 71. For example, when the sheet resistance of the 2DEG 20 is 500 Ω/sq, the width of the connection path 71 is 1 μm, and the length of the connection path 71 is 1,000 μm, the resistance value R of the connection path 71 can be set to 500 kQ (R=500 [Ω/sq]×1000 [μm]/1 [μm]).

### [6-2. Second Structure Example of Resistive Element]

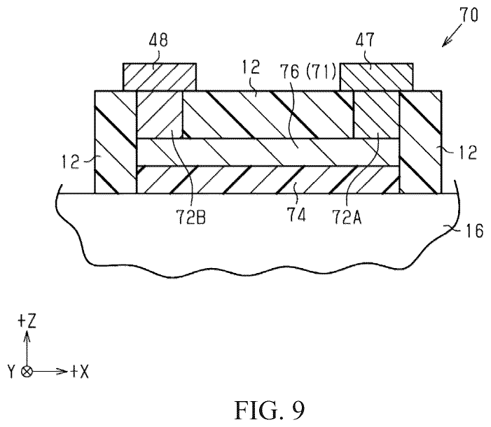

FIG. 9 is a schematic cross-sectional view of a second structure example of the resistive element 70. In the second structure example, the resistive element 70 includes an insulating film 74 formed on the electron transport layer 16 and a conductive layer 76 formed on the insulating film 74. An example of the material of the conductive layer 76 is polysilicon. However, the material is not limited to polysilicon, and any other conductive material may be used for the conductive layer 76. The resistive element 70 of the second structure example has the path of the conductive layer 76 as the connection path 71. For example, in the area where the resistive element 70 is formed, the conductive layer 76 is formed to be meandering when viewed from above, following the shape shown as the connection path 71 in FIG. 1. Thereby, the connection path 71 using the conductive layer 76 is meanderingly formed.

The resistive element 70 of the second structure example includes a first terminal 72A and a second terminal 72B electrically connected to both ends of the connection path 71 formed by the conductive layer 76. The first terminal 72A and the second terminal 72B may be provided to directly connect to the conductive layer 76. Like the first structure example, in the second structure example, for example, the same metal material as the source electrode 28 and the drain electrode 30 may be used for the first terminal 72A and the second terminal 72B. The first pad 47 is connected to the upper end of the first terminal 72A, and the second pad 48 is connected to the upper end of the second terminal 72B. In the resistive element 70 of the second structure example, the resistance value R of the connection path 71 is set based on the length and width of the conductive layer 76 formed as the connection path 71.

### [7. Nitride Semiconductor Module]

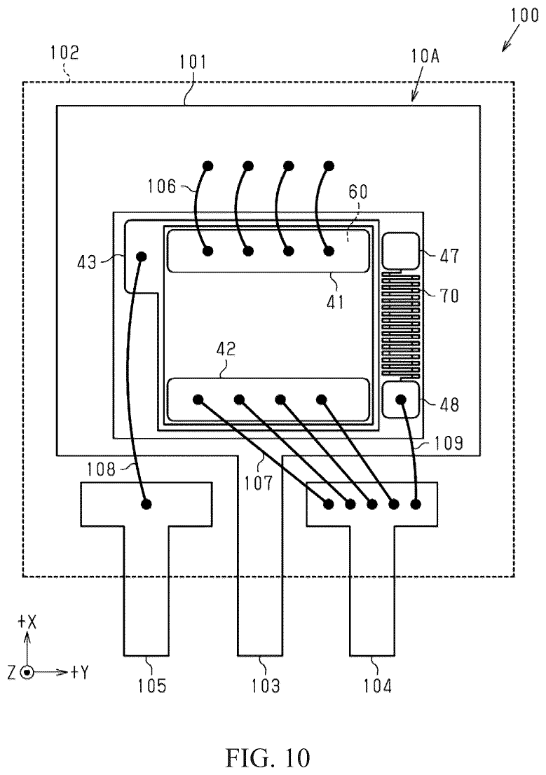

Next, an exemplary structure of a nitride semiconductor module 100 including the nitride semiconductor device 10A of FIG. 1 will be described with reference to FIGS. 10 to 13. Two mounting examples of the nitride semiconductor device 10A will be described below.

### [7-1. First Mounting Example of Nitride Semiconductor Device]

FIG. 10 is a schematic plan view of the nitride semiconductor module 100 including the wire-mounted nitride semiconductor device 10A according to the first mounting example.

The nitride semiconductor module 100 includes a chip pad 101, a nitride semiconductor device 10A mounted on the chip pad 101, and a sealing resin 102 that seals the nitride semiconductor device 10A. The chip pad 101 is formed in a rectangular plate shape. The chip pad 101 is formed of, for example, copper (Cu) or an alloy containing copper. The sealing resin 102 is formed of an insulating resin material such as epoxy resin, acrylic resin, or phenolic resin.

The nitride semiconductor module 100 includes a source lead 103, a drain lead 104, and a gate lead 105 that are partially exposed from the sealing resin 102. The source lead 103 is integrally formed with the chip pad 101.

The nitride semiconductor module 100 also includes a source wire 106, a drain wire 107, and a gate wire 108. The source wire 106 connects the chip pad 101 (i.e., the source lead 103) to the source pad 41. The drain wire 107 connects the drain lead 104 to the drain pad 42. The gate wire 108 connects the gate lead 105 to the gate pad 43. The source wire 106, the drain wire 107 and the gate wire 108 are sealed with the sealing resin 102.

The nitride semiconductor module 100 also includes a specific wire 109. The specific wire 109 connects the second pad 48 to the drain lead 104. Therefore, the second pad 48 is set to the drain potential via the specific wire 109. The specific wire 109 is sealed by the sealing resin 102. In addition, in this disclosure, the specific wire 109 corresponds to the first wire.

The source wire 106, the drain wire 107, the gate wire 108 and the specific wire 109 are bonding wires formed by a wire bonding device (not shown), and are formed of, for example, conductor materials such as gold (Au), Al, and Cu. Additionally, each of the wires may be formed of the same material (e.g., Cu), or at least one of the wires may be formed of a different material than the other wires.

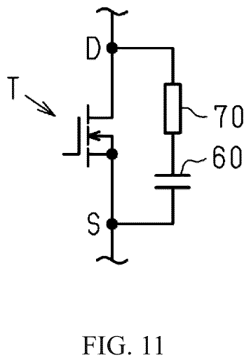

FIG. 11 is an equivalent circuit diagram of a switching element with an RC snubber circuit provided in the nitride semiconductor module 100 of FIG. 10. That is, the first mounting example shows an example in which the nitride semiconductor device 10A is mounted as a switching element with an RC snubber circuit by applying a drain potential to the second pad 48 using the specific wire 109.

In the first mounting example, the second pad 48 is connected to the drain lead 104 using the specific wire 109 (that is, the second pad 48 is set to the drain potential), so that the resistive element 70 is electrically connected to the drain terminal D of the transistor T (referring to FIG. 11). Therefore, the first pad 47 is electrically connected to the drain terminal D via the resistive element 70. Here, the first pad 47 is electrically connected to the second electrode 62A of the capacitive element 60 (referring to FIG. 7), and the first electrode 41A of the capacitive element 60 is set to the source potential. Therefore, between the drain terminal D and the source terminal S of the transistor T (referring to FIG. 11), the resistive element 70 and the capacitive element 60 are connected in series. As a result, in the nitride semiconductor module 100 of the first mounting example, the nitride semiconductor device 10A of FIG. 1 can be mounted as the switching element with the RC snubber circuit.

### [7-2. Second Mounting Example of Nitride Semiconductor Device]

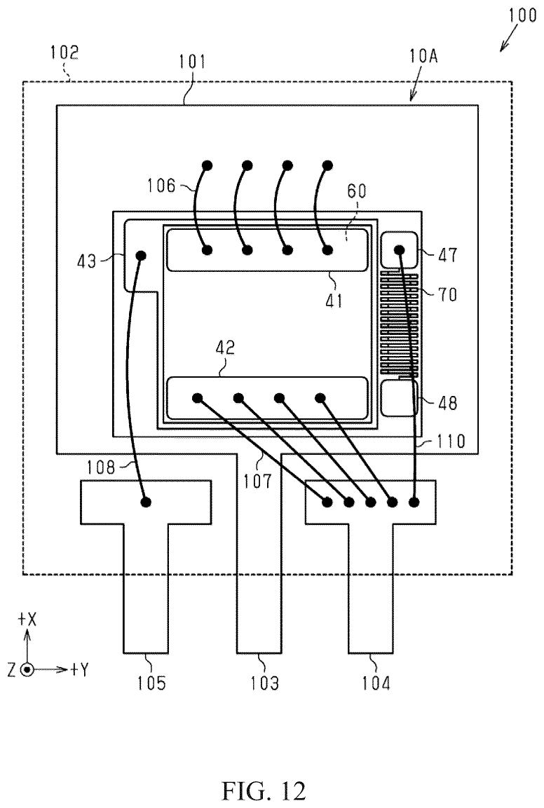

FIG. 12 is a schematic plan view of the nitride semiconductor module 100 including the nitride semiconductor device 10A wire-mounted according to the second mounting example.

In addition, in the second mounting example, a specific wire 110 is used instead of the specific wire 109 in the first mounting example, and the other configuration is the same as that of the nitride semiconductor module 100 in FIG. 11. Therefore, a detailed description of the same configuration as that of the nitride semiconductor module 100 in FIG. 11 will be omitted. In addition, in this disclosure, the specific wire 110 corresponds to the second wire.

The specific wire 110 connects the first pad 47 to the drain lead 104. Therefore, the first pad 47 is set to the drain potential via the specific wire 110. The specific wire 110 is sealed by the sealing resin 102. The specific wire 110 may be formed of the same conductor material as the specific wire 109. In addition, in the second mounting example, the second pad 48 remains without potential.

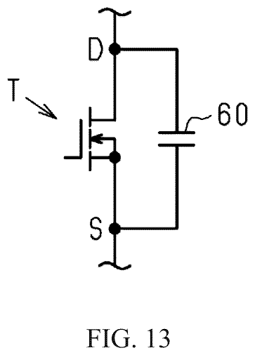

FIG. 13 is an equivalent circuit diagram of a switching element with a C snubber circuit provided in the nitride semiconductor module 100 of FIG. 12. That is, the second mounting example shows an example in which the nitride semiconductor device 10A is mounted as a switching element with a C snubber circuit by applying a drain potential to the first pad 47 using the specific wire 110.

In the second mounting example, by connecting the first pad 47 to the drain lead 104 using the specific wire 110 (that is, setting the first pad 47 to the drain potential), the capacitive element 60 is electrically connected to the drain terminal D of the transistor T (referring to FIG. 13). As described above, the first pad 47 is electrically connected to the second electrode 62A of the capacitive element 60 (referring to FIG. 7), and the first electrode 41A of the capacitive element 60 is set to the source potential. Therefore, the capacitive element 60 is connected between the drain terminal D and the source terminal S of the transistor T (referring to FIG. 13). Here, since the second pad 48 remains without potential, the resistive element 70 is not connected between the drain terminal D and the source terminal S. In this way, in the nitride semiconductor module 100 of the second mounting example, the nitride semiconductor device 10A of FIG. 1 can be mounted as the switching element with the C snubber circuit.

### [8. Function]

Next, the functions of the nitride semiconductor device 10A and the nitride semiconductor module 100 of the first embodiment will be described.

The nitride semiconductor device 10A includes the transistor T (switching element), the capacitive element 60 electrically connected to the source electrode 28 of the transistor T, and the first pad 47 electrically connected to the capacitive element 60. In addition, the nitride semiconductor device 10A includes the resistive element 70 electrically connected to the first pad 47 and the second pad 48 electrically connected to the resistive element 70. The nitride semiconductor device 10A has the first pad 47 and the second pad 48 as potential-free pads in the chip state.

The nitride semiconductor HEMT, that is, the transistor T, is provided as a high-speed switching element. The transistor T takes advantage of low switching losses to bring high conversion efficiency. On the other hand, with high-speed switching, the shorter the switching transition time, the easier it is to generate voltage surges and voltage ringing (circuit resonance) during switching. Therefore, voltage surge countermeasures and voltage ringing countermeasures are taken in accordance with the requirements of the system side that incorporates the transistor T. The nitride semiconductor device 10A has a chip structure that can meet the above requirements.

According to the nitride semiconductor device 10A, when it is provided as the nitride semiconductor module 100, it is possible to select whether to install it as a switching element with an RC snubber circuit (FIG. 10) or to install it as a switching element with a C snubber circuit (FIG. 12). Therefore, the nitride semiconductor device 10A has a chip structure capable of selectively adding one of the RC snubber circuit and the C snubber circuit to the transistor T (switching element). Accordingly, for example, voltage surge countermeasures and voltage ringing countermeasures can be taken according to the requirements of the system side in which the nitride semiconductor device 10A is mounted. In addition, generally speaking, as the operating frequency becomes higher, the power consumption of the resistive element 70 in the RC snubber circuit increases. Therefore, for example, when the operating frequency is high, a C snubber circuit may be selected instead of the RC snubber circuit.

Here, when a snubber circuit is added to a transistor (switching element), the drain-source capacitance of the transistor increases, so the switching speed decreases. As a result, power supply efficiency decreases because switching losses increase. Therefore, in order to maximize the high-speed switching characteristics of the nitride semiconductor HEMT, it is desirable to install only the transistor T without adding a snubber circuit when voltage surge countermeasures and voltage ringing countermeasures are not required.

According to the nitride semiconductor device 10A, when a snubber circuit is not required (that is, when voltage surge countermeasures and voltage ringing countermeasures are not required), it suffices to keep the first pad 47 and the second pad 38 as potential-free pads when mounted on the nitride semiconductor module 100. Thus, since only the transistor T (switching element) is mounted, the high-speed switching characteristics of the nitride semiconductor HEMT can be utilized to the maximum extent.

The nitride semiconductor device 10A and the nitride semiconductor module 100 of the first embodiment have the following advantages.

(1-1)

The nitride semiconductor device 10A includes a transistor T as a switching element, a capacitive element 60, a resistive element 70, a first pad 47, and a second pad 48. The nitride semiconductor device 10A functions as a switching element with an RC snubber circuit (FIG. 10) by applying a drain potential to the second pad 48, and functions as a switching element with a C snubber circuit (FIG. 12) by applying a drain potential to the first pad 47. Therefore, it is possible to provide a chip structure capable of selectively mounting either a switching element with an RC snubber circuit or a switching element with a C snubber circuit. Thereby, voltage surge countermeasures and voltage ringing countermeasures can be taken as needed.

(1-2)

When the nitride semiconductor device 10A does not require a snubber circuit (that is, when voltage surge countermeasures and voltage ringing countermeasures are not required), the first pad 47 and the second pad 48 are mounted as potential-free pads. In such case, since only the transistor T (switching element) is mounted, the high-speed switching characteristics of the nitride semiconductor HEMT can be utilized to the maximum extent.

(1-3)

The capacitive element 60 has an opposing area S, an inter-electrode distance d, and a specific capacitance Cₛₚ corresponding to the dielectric constant ε of the dielectric layer 12C. The opposing area S depends on the respective areas of the first electrode 41A and the second electrode 62A, and the inter-electrode distance d depends on the distance between the first electrode 41A and the second electrode 62A. The dielectric constant ε of the dielectric layer 12C depends on the type of the dielectric layer 12C (the material of the insulating layer 12). Therefore, by changing the parameter, the specific capacitance Cₛₚ of the capacitive element 60 of the snubber circuit can be set to an arbitrary value.

(1-4)

The first electrode 41A of the capacitive element 60 is formed using the source pad 41, and the dielectric layer 12C of the capacitive element 60 is formed using the insulating layer 12. Therefore, the capacitive element 60 can be formed by adding the electrode layer 62 including the second electrode 62A. Thus, the capacitive element 60 for the snubber circuit can be easily formed using the component provided for the transistor T (switching element).

(1-5)

The dielectric layer 12C of the capacitive element 60 is formed of the same material as the insulating layer 12 and is located on the same layer as the insulating layer 12. According to the above configuration, even if the capacitive element 60 is added, the chip thickness does not increase.

(1-6)

The first pad 47, the second pad 48, the capacitive element 60, and the resistive element 70 are provided in the peripheral region A2 surrounding the active region A1 in which the transistor T (switching element) is installed. According to the above configuration, the first pad 47, the second pad 48, the capacitive element 60 and the resistive element 70 can be arranged using the empty space in the peripheral region A2. Therefore, an increase in the chip size of the nitride semiconductor device 10A due to the addition of snubber circuits (RC snubber circuit and C snubber circuit) can be suppressed.

(1-7)

The first pad 47 is located near the source pad 41 in a plan view. According to the above configuration, it is not only easy to form the electrode layer 62 that spans both the source pad 41 and the first pad 47 in a plan view, but also capable of reducing the size of the electrode layer 62. This can suppress an increase in the chip size of the nitride semiconductor device 10A.

(1-8)

In addition, the second pad 48 is located near the drain pad 42 in a plan view. According to the above configuration, the empty space in the peripheral region A2 can be effectively used to form the resistive element 70 connected between the first pad 47 and the second pad 48.

(1-9)

The gate layer 22 in the transistor T (switching element) is formed of a nitride semiconductor containing acceptor-type impurities. According to the above configuration, the normally-off transistor T can be provided.

(1-10)

The electrode layer 62 including the second electrode 62A may be formed of the same material as the gate electrode 24. In such case, since the electrode layer 62 (the second electrode 62A) can be formed simultaneously with the patterning of the gate electrode 24, no additional manufacturing steps are required.

(1-11)

Alternatively, the electrode layer 62 including the second electrode 62A may be formed of the same material as the source electrode 28 and the drain electrode 30. In such case, since the electrode layer 62 (the second electrode 62A) can be formed simultaneously with the patterning of the source electrode 28 and the drain electrode 30, no additional manufacturing steps are required.

(1-12)

The nitride semiconductor module 100 is provided as a switching element with an RC snubber circuit (FIG. 10) by wire connecting the second pad 48 to the drain lead 104. In addition, the nitride semiconductor module 100 is provided as a switching element with a C snubber circuit (FIG. 12) by wire connecting the first pad 47 to the drain lead 104. Therefore, it is possible to selectively add one of the RC snubber circuit and the C snubber circuit to the transistor T (switching element) simply by changing the wire connection position.

### Second Embodiment

Next, the nitride semiconductor device 10B of the second embodiment will be described with reference to FIG. 14. In the second embodiment, the structure of the capacitive element 60 and its connection structure in the first embodiment are changed, and the other structures are the same as those in the first embodiment. Hereinafter, the description of the same structural elements as those in the first embodiment will be omitted, and the structural elements that are different from the first embodiment will be described.

FIG. 14 is a partial schematic cross-sectional view of an exemplary nitride semiconductor device 10B according to the second embodiment. In addition, the cross-sectional structure of FIG. 14 is shown as corresponding to the cross-sectional structure of FIG. 7 according to the first embodiment.

In the second embodiment, an electrode layer 64 is provided instead of the electrode layer 62 (referring to FIG. 7) of the first embodiment. The electrode layer 64 at least partially overlaps the source pad 41 in a plan view, and is provided in contact with the lower surface of the dielectric layer 12C. For example, the electrode layer 64 may be formed to overlap the entire source pad 41 and have the same size as the source pad 41 in a plan view. Alternatively, the electrode layer 64 may be formed smaller than the source pad 41 in a plan view so as to overlap a portion of the source pad 41. In the second embodiment, the entire electrode layer 64 is provided as the second electrode 64A of the capacitive element 60.

Below the electrode layer 64, a conductive layer 66 is provided across both the source pad 41 and the first pad 47 in a plan view. In the area where the conductive layer 66 and the first pad 47 overlap in a plan view, a via hole V1 is formed penetrating the insulating layer 12 between the conductive layer 66 and the first pad 47 to electrically connect the conductive layer 66 to the first pad 47. In addition, the via hole V1 is an example of the first through conductor.

In addition, in the area where the conductive layer 66 and the electrode layer 64 overlap in a plan view, a via hole V2 is formed penetrating the insulating layer 12 between the conductive layer 66 and the electrode layer 64 to electrically connect the conductive layer 66 to the electrode layer 64 (the second electrode 64A). Therefore, the first pad 47 is electrically connected to the second electrode 64A via the via hole V1, the conductive layer 66, and the via hole V2. In addition, the via hole V2 is an example of the second through conductor.

The insulating layer 12 interposed between the conductive layer 66 and the electrode layer 64 may be, for example, a passivation layer (such as SiN, etc.) formed on the electron supply layer 18 to cover the insulating layer 26, that is, the gate electrode 24 of the transistor T (referring to FIG. 2). Therefore, the material of the dielectric layer 12C may be different from the material of the insulating layer 26 interposed between the conductive layer 66 and the electrode layer 64. In addition, in the second embodiment, the insulating layer 12 provided between the first pad 47 and the conductive layer 66 corresponds to the first insulating layer. In addition, the insulating layer 26 provided between the electrode layer 64 and the conductive layer 66 corresponds to the second insulating layer.

The electrode layer 64 may be made of any conductor material including at least one of Cu, Al, AlSiCu, AlCu, W, Ti, and TiN, for example. An example of the material of the electrode layer 64 is the same material as the source electrode 28 and the drain electrode 30, such as AlCu. In such instance, the electrode layer 64 is formed by patterning simultaneously with the source electrode 28 and the drain electrode 30.

Likewise, the conductive layer 66 may be made of any conductor material including at least one of Cu, Al, AlSiCu, AlCu, W, Ti, and TiN, for example. An example of the material of the conductive layer 66 is the same material as the gate electrode 24, such as TiN. In such instance, the conductive layer 66 is formed by patterning simultaneously with the gate electrode 24.

In addition to the same advantages as (1-1) to (1-4) and (1-6) to (1-12) of the first embodiment or advantages based thereon, the nitride semiconductor device 10B of the second embodiment also has the following advantages.

(2-1)

In the second embodiment, the electrode layer 64 provided as the second electrode 64A is embedded in the insulating layer located above the conductive layer 66, that is, between the insulating layer 12 and the insulating layer 26. In this way, the second electrode 64A of the capacitive element 60 can also be formed using the electrode layer 64 arranged in a different layer position from the conductive layer 66 connected to the first pad 47 via the via hole V1. According to this configuration, the degree of freedom in designing the capacitive element 60 is improved.

### Modified Examples

Each of the embodiments described above can be modified as follows, for example. Each of the above-described embodiments and each of the following modified examples can be combined with each other as long as there is no technical contradiction. In addition, in the following modified examples, the same reference numerals as those in each of the above-described embodiments are labeled respectively to portions that are common to each of the above-described embodiments, and descriptions thereof are omitted.

In the nitride semiconductor module 100, the configuration of setting the first pad 47 or the second pad 48 to the drain potential is not limited to the configuration using the bonding wire connection described with reference to FIGS. 10 and 12. For example, the nitride semiconductor module 100 may be configured without using bonding wires like a chip-scale package. Hereinafter, as examples of flip-chip mounting instead of wire mounting, a case of a switching element mounted with an RC snubber circuit and a case of a switching element mounted with a C snubber circuit will be illustrated respectively.

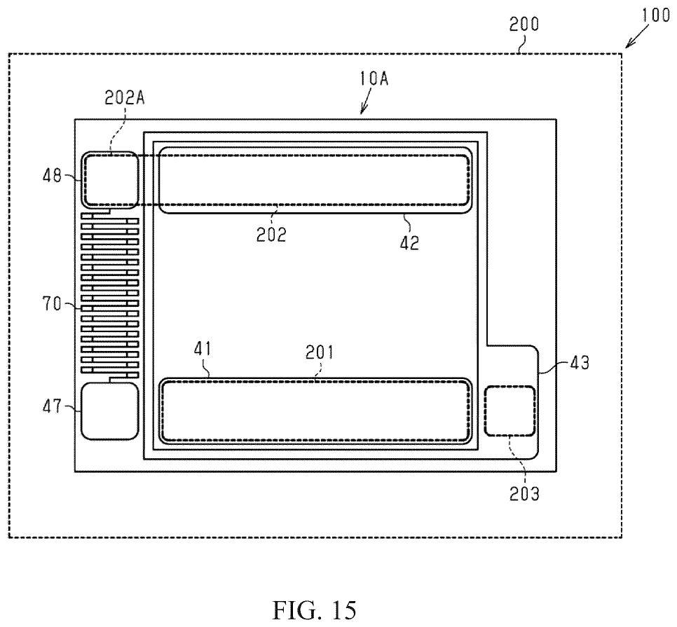

FIG. 15 is a schematic plan view of the nitride semiconductor module 100 including the nitride semiconductor device 10A that is flip-chip mounted according to a third mounting example. In addition, FIG. 15 is a diagram showing a state in which the nitride semiconductor device 10A is flip-chip mounted on a mounting substrate 200 such as a printed wiring substrate as viewed from the back side of the mounting substrate 200. In order to see through the nitride semiconductor device 10A, a dotted line is used to indicate the mounting substrate 200.

The mounting substrate 200 has a mounting surface on which the nitride semiconductor device 10A is mounted. On the mounting surface of the mounting substrate 200, a source connection portion 201 connected to the source pad 41, a drain connection portion 202 connected to the drain pad 42, and a gate connection portion 203 connected to the gate pad 43 are formed as a plurality of wiring portions. In addition, the drain connection portion 202 is integrally formed with a first connection extension portion 202A. The first connection extension portion 202A extends from the drain connection portion 202 and connects the second pad 48 to the drain pad 42. Even when such a third mounting example is used, the nitride semiconductor device 10A can be mounted as a switching element with an RC snubber circuit, as the instance of the first mounting example of FIG. 10 (wire mounting using the specific wire 109).

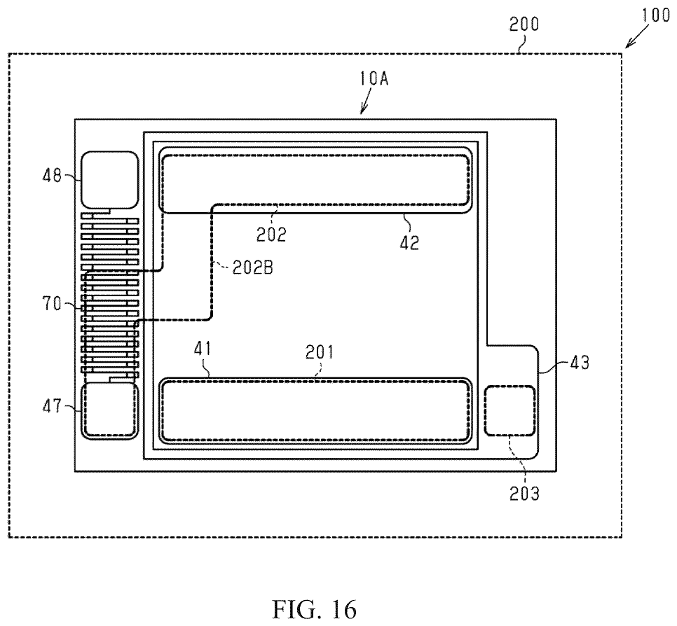

FIG. 16 is a schematic plan view of the nitride semiconductor module 100 including the nitride semiconductor device 10A that is flip-chip mounted according to a fourth mounting example. Similar to FIG. 15, FIG. 16 is a diagram showing a state in which the nitride semiconductor device 10A is flip-chip mounted on the mounting substrate 200 when viewed from the back side of the mounting substrate 200. In order to see through the nitride semiconductor device 10A, a dotted line is used to indicate the mounting substrate 200.

In the fourth mounting example, as in the third mounting example of FIG. 15, the source connection portion 201, the drain connection portion 202, and the gate connection portion 203 are formed on the mounting surface of the mounting substrate 200 as a plurality of wiring portions. The drain connection portion 202 is integrally formed with a second connection extension portion 202B. The second connection extension portion 202B extends from the drain connection portion 202 and connects the first pad 47 to the drain pad 42. In addition, the shape (wiring pattern) of the second connection extension portion 202B is not particularly limited. Even in the case of using such a fourth mounting example, the nitride semiconductor device 10A can be mounted as a switching element with a C snubber circuit, as the instance of the second mounting example of FIG. 12 (wire mounting using the specific wire 110).

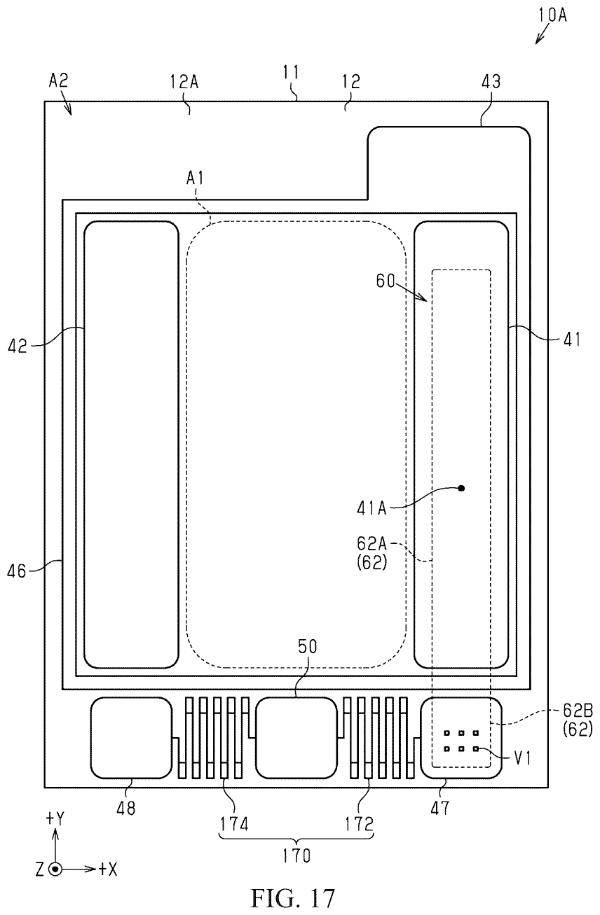

FIG. 17 is a schematic plan view of a nitride semiconductor device 10A according to a modified example. As shown in FIG. 17, in addition to the first pad 47 and the second pad 48, a third pad 50 may be provided. In the modified example, the nitride semiconductor device 10A includes a resistive element 170 instead of the resistive element 70 in FIG. 1. The resistive element 170 includes a first resistive element portion 172 electrically connected to the first pad 47 and a second resistive element portion 174 electrically connected to the second pad 48. The third pad 50 is provided between the first resistive element portion 172 and the second resistive element portion 174 and is electrically connected to the first resistive element portion 172 and the second resistive element portion 174.

In the modified example of FIG. 17, the first pad 47 is set to the drain potential, so that the nitride semiconductor device 10A is mounted as a switching element with a C snubber circuit. In addition, by setting the second pad 48 or the third pad 50 to the drain potential, the nitride semiconductor device 10A is mounted as a switching element with an RC snubber circuit. At this time, when the second pad 48 is used, the resistance value of the snubber circuit is determined by the entire resistive element 170 including the first and second resistive element portions 172 and 174. When the third pad 50 is used, the resistance value of the snubber circuit is determined by the first resistive element portion 172. Therefore, the resistance value of the RC snubber circuit can be selected.

Alternatively, two or more specific pads may be provided between the first pad 47 and the second pad 48. In this case, the resistance value of the RC snubber circuit installed by the nitride semiconductor device 10A (or the nitride semiconductor device 10B) can be selected more precisely.

In each of the above-described embodiments and modified examples, each of the nitride semiconductor devices 10A and 10B includes the capacitive element 60, the resistive element 70, the first pad 47, and the second pad 48 together with the transistor T (switching element). However, the resistive element 70 and the second pad 48 may be omitted. That is, each of the nitride semiconductor devices 10A and 10B may be configured to include only the capacitive element 60 and the first pad 47 together with the transistor T (switching element) so that only the switching element with the C snubber circuit can be mounted.

Regarding each electrode pad involving the source pad 41, the drain pad 42 or the gate pad 43, the plan view shape, number, and arrangement on the upper surface 12A of the insulating layer 12 are not limited to the above embodiments. In addition, regarding the first pad 47 and the second pad 48, the plan view shape and the arrangement on the upper surface 12A of the insulating layer 12 are not limited to the above-described embodiments.

In each of the above embodiments, the transistor T is not limited to a normally-off type, and may also be implemented as a normally-on type. In this case, the gate layer 22 does not contain acceptor-type impurities.

In each of the above embodiments, the gate layer 22 may not include the first extension portion 22B and the second extension portion 22C, and may be formed only of the gate layer main body portion 22A.

In each of the above embodiments, the arrangement of the active region A1 and the peripheral region A2 is not limited to the layout shown in FIG. 1.

The term “on” used in this disclosure includes both “on” and “above” unless the context clearly indicates otherwise. Therefore, the expression “the first layer is formed on the second layer” is intended to mean that in a certain embodiment the first layer may be in contact with the second layer and directly disposed on the second layer, but in other embodiment the first layer may not be in contact with the second layer and arranged above the second layer. In other words, the term “on” does not exclude the structure in which other layer is formed between the first layer and the second layer.

The Z-axis direction used in this disclosure may not be the vertical direction, nor may it be completely consistent with the vertical direction. Therefore, the various structures of the present disclosure (for example, the structures shown in FIGS. 2 and 3) are not limited to the “upper” and “lower” in the Z-axis direction explained in this specification being the “upper” and “lower” in the vertical direction. For example, the X-axis direction may also be a vertical direction, or the Y-axis direction may also be a vertical direction.

The terms such as “first”, “second”, and “third” in this disclosure are used only to distinguish the objects and do not rank the objects.

### <Note>

The technical idea that can be understood from this disclosure are described below. Note that, not for the purpose of limitation but for the purpose of aiding understanding, the components described in the note are given the reference numerals of the corresponding components in the embodiment. Reference numerals are shown by way of example to aid understanding, and the components described in each note should not be limited to the components indicated by the reference numerals.

### (Note A1)

A nitride semiconductor device (10A, 10B), comprising:
a switching element (T), formed of a nitride semiconductor and including a source electrode (28), a drain electrode (30) and a gate electrode (24);
a source pad (41), electrically connected to the source electrode (28);
a drain pad (42), electrically connected to the drain electrode (30);
a gate pad (43), electrically connected to the gate electrode (24);
a capacitive element (60), electrically connected to the source electrode (28);
a first pad (47), electrically connected to the capacitive element (60);
a resistive element (70, 170), electrically connected to the first pad (47); and
a second pad (48), electrically connected to the resistive element (70, 170).

### (Note A2)

The nitride semiconductor device (10A, 10B) of Note A1, comprising:
an electrode layer (62, 64), at least partially overlapping the source pad (41) in a plan view and electrically connected to the first pad (47); and
a dielectric layer (12C), disposed between the source pad (41) and the electrode layer (62, 64), wherein
the source pad (41) includes a portion overlapping with the electrode layer (62, 64) in the plan view as a first electrode (41A) corresponding to one of two opposing electrodes of the capacitive element (60), and
the electrode layer (62, 64) includes a portion overlapping with the source pad (41) in the plan view as a second electrode (62A, 64A) corresponding to another one of the two opposing electrodes of the capacitive element (60).

### (Note A3)

The nitride semiconductor device (10A, 10B) of Note A2, wherein
the electrode layer (62) is disposed across both the source pad (41) and the first pad (47) in the plan view,
an insulating layer (12) is disposed between the first pad (47) and the electrode layer (62); and
the first pad (47) is connected to the electrode layer (62) via a first through conductor (V1) penetrating the insulating layer (12).

### (Note A4)

The nitride semiconductor device (10A) of Note A3, wherein the dielectric layer (12C) is formed of a material same as a material of the insulating layer (12) and is located at same layer of the insulating layer (12).

### (Note A5)

The nitride semiconductor device (10B) of Note A2, comprising:
a conductive layer (66), located below the electrode layer (64) and disposed across both the source pad (41) and the first pad (47) in the plan view;
a first insulating layer (12), disposed between the first pad (47) and the conductive layer (66);
a second insulating layer (26), disposed between the electrode layer (64) and the conductive layer (66), wherein
the first pad (47) is connected to the conductive layer (66) via a first through conductor (V1) penetrating the first insulating layer (12), and
the electrode layer (64) is connected to the conductive layer (66) via a second through conductor (V2) penetrating the second insulating layer (26).

### (Note A6)

The nitride semiconductor device (10B) of Note A5, wherein
the dielectric layer (12C) is made of a material same as a material of the first insulating layer (12), and
the second insulating layer (26) is made of a material different from the material of the first insulating layer (12).

### (Note A7)

The nitride semiconductor device (10B) of Note A5 or Note A6, wherein
the second insulating layer (26) is a layer covering the gate electrode (24) of the switching element (T), and
the first insulating layer (12) is a layer covering the source electrode (28) and the drain electrode (30) of the switching element (T).

### (Note A8)

The nitride semiconductor device (10A, 10B) of any one of Notes A1 to A7, wherein
the resistive element (170) includes a first resistive element portion (172) electrically connected to the first pad (47), and a second resistive element portion (174) electrically connected to the second pad (48), and
the nitride semiconductor device (10A, 10B) further comprises a third pad (50) disposed between the first resistive element portion (172) and the second resistive element portion (174) and electrically connected to the first resistive element portion (172) and the second resistive element portion (174).

### (Note A9)

The nitride semiconductor device (10A, 10B) of any one of Notes A1 to A8, wherein
the switching element (T) is disposed in an active region (A1), and
the first pad (47), the second pad (48), the capacitive element (60) and the resistive element (70, 170) are arranged in a peripheral region (A2) surrounding the active region (A1) in a plan view.

### (Note A10)

The nitride semiconductor device (10A, 10B) of any one of Notes A1 to A9, wherein the first pad (47) is located adjacent to the source pad (41) in a plan view.

### (Note A11)

The nitride semiconductor device (10A, 10B) of Note A10, wherein the second pad (48) is located adjacent to the drain pad (42) in a plan view.

### (Note A12)

The nitride semiconductor device (10A, 10B) of any one of Notes A1 to A11, wherein the switching element (T) includes:
an electron transport layer (16), made of a first nitride semiconductor;
an electron supply layer (18), disposed on the electron transport layer (16) and made of a second nitride semiconductor having a larger band gap than that of the first nitride semiconductor;
a gate layer (22), disposed on a portion of the electron supply layer (18) and made of a third nitride semiconductor containing acceptor-type impurities;
the gate electrode (24), disposed on the gate layer (22); and
the source electrode (28) and the drain electrode (30), in contact with the electron supply layer (18).

### (Note A13)

The nitride semiconductor device (10A, 10B) of Note A2, wherein
the switching element (T) is disposed in an active region (A1),
the first pad (47), the second pad (48), the capacitive element (60) and the resistive element (70, 170) are arranged in a peripheral region (A2) surrounding the active region (A1) in a plan view, and
the electrode layer (62) is disposed on an outer peripheral portion formed of a nitride semiconductor in the peripheral region (A2).

### (Note A14)

The nitride semiconductor device (10A, 10B) of any one of Notes A2 to A7, wherein the electrode layer (62, 64) is made of a material same as a material of the gate electrode (24).

### (Note A15)

The nitride semiconductor device (10A, 10B) of any one of Notes A2 to A7, wherein the electrode layer (62, 64) is made of a material same as a material of the source electrode (28) and a material of the drain electrode (30).

### (Note A16)

The nitride semiconductor device (10A, 10B) of any one of Notes A2 to A7, wherein the electrode layer (62, 64) is formed of at least one of Cu, Al, AlSiCu, AlCu, W, Ti and TiN.

### (Note A17)

A nitride semiconductor module (100), comprising:
the nitride semiconductor device (10A, 10B) of any one of Notes A1 to A16;
a source lead (103), a drain lead (104) and a gate lead (105);
a source wire (106), connecting the source lead (103) to the source pad (41);
a drain wire (107), connecting the drain lead (104) to the drain pad (42);
a gate wire (108), connecting the gate lead (105) to the gate pad (43); and
a first wire (109), connecting the second pad (48) to the drain lead (104).

### (Note A18)

A nitride semiconductor module (100), comprising:
the nitride semiconductor device (10A, 10B) of any one of Notes A1 to A16;
a source lead (103), a drain lead (104) and a gate lead (105),
a source wire (106), connecting the source lead (103) to the source pad (41);
a drain wire (107), connecting the drain lead (104) to the drain pad (42);
a gate wire (108), connecting the gate lead (105) to the gate pad (43); and
a second wire (110), connecting the first pad (47) to the drain lead (104).

### (Note A19)

A nitride semiconductor module (100), comprising:
the nitride semiconductor device (10A, 10B) of any one of Notes A1 to A16; and
a mounting board (200), on which the nitride semiconductor device (10A, 10B) is flip-chip mounted, wherein the mounting board (200) includes:
   a source connecting portion (201), connected to the source pad (41);
   a drain connecting portion (202), connected to the drain pad (42);
   a gate connecting portion (203), connected to the gate pad (43); and
   a first connecting extension portion (202A), extending from the drain connecting portion (202) and connecting the second pad (48) to the drain pad (42).

### (Note A20)

A nitride semiconductor module (100), comprising:
the nitride semiconductor device (10A, 10B) of any one of Notes A1 to A16; and
a mounting board (200), on which the nitride semiconductor device (10A, 10B) is flip-chip mounted, wherein the mounting board (200) includes:
   a source connecting portion (201), connected to the source pad (41);
   a drain connecting portion (202), connected to the drain pad (42);
   a gate connecting portion (203), connected to the gate pad (43); and
   a second connecting extension portion (202B), extending from the drain connection portion (202) and connecting the first pad (47) to the drain pad (42).

### (Note B1)

A nitride semiconductor device (10A, 10B), comprising:
a switching element (T), formed of a nitride semiconductor and including a source electrode (28), a drain electrode (30) and a gate electrode (24);
a source pad (41), electrically connected to the source electrode (28);
a drain pad (42), electrically connected to the drain electrode (30);
a gate pad (43), electrically connected to the gate electrode (24);
a capacitive element (60), electrically connected to the source electrode (28); and
a first pad (47), electrically connected to the capacitive element (60).

1. A nitride semiconductor device, comprising:
a switching element, formed of a nitride semiconductor and including a source electrode, a drain electrode and a gate electrode;
a source pad, electrically connected to the source electrode;
a drain pad, electrically connected to the drain electrode;
a gate pad, electrically connected to the gate electrode;
a capacitive element, electrically connected to the source electrode;
a first pad, electrically connected to the capacitive element;
a resistive element, electrically connected to the first pad; and
a second pad, electrically connected to the resistive element.

2. The nitride semiconductor device of claim 1, comprising:
an electrode layer, at least partially overlapping the source pad in a plan view and electrically connected to the first pad; and
a dielectric layer, disposed between the source pad and the electrode layer, wherein
the source pad includes a portion overlapping with the electrode layer in the plan view as a first electrode corresponding to one of two opposing electrodes of the capacitive element, and
the electrode layer includes a portion overlapping with the source pad in the plan view as a second electrode corresponding to another one of the two opposing electrodes of the capacitive element.

3. The nitride semiconductor device of claim 2, wherein
the electrode layer is disposed across both the source pad and the first pad in the plan view,
an insulating layer is disposed between the first pad and the electrode layer; and
the first pad is connected to the electrode layer via a first through conductor penetrating the insulating layer.

4. The nitride semiconductor device of claim 3, wherein the dielectric layer is formed of a material same as a material of the insulating layer and is located at same layer of the insulating layer.

5. The nitride semiconductor device of claim 2, comprising:
a conductive layer, located below the electrode layer and disposed across both the source pad and the first pad in the plan view;
a first insulating layer, disposed between the first pad and the conductive layer;
a second insulating layer, disposed between the electrode layer and the conductive layer, wherein
the first pad is connected to the conductive layer via a first through conductor penetrating the first insulating layer, and
the electrode layer is connected to the conductive layer via a second through conductor penetrating the second insulating layer.

6. The nitride semiconductor device of claim 5, wherein
the dielectric layer is made of a material same as a material of the first insulating layer, and
the second insulating layer is made of a material different from the material of the first insulating layer.

7. The nitride semiconductor device of claim 5, wherein
the second insulating layer is a layer covering the gate electrode of the switching element, and
the first insulating layer is a layer covering the source electrode and the drain electrode of the switching element.

8. The nitride semiconductor device of claim 1, wherein
the resistive element includes a first resistive element portion electrically connected to the first pad, and a second resistive element portion electrically connected to the second pad, and
the nitride semiconductor device further comprises a third pad disposed between the first resistive element portion and the second resistive element portion and electrically connected to the first resistive element portion and the second resistive element portion.

9. The nitride semiconductor device of claim 1, wherein
the switching element is disposed in an active region, and
the first pad, the second pad, the capacitive element and the resistive element are arranged in a peripheral region surrounding the active region in a plan view.

10. The nitride semiconductor device of claim 1, wherein the first pad is located adjacent to the source pad in a plan view.

11. The nitride semiconductor device of claim 10, wherein the second pad is located adjacent to the drain pad in a plan view.

12. The nitride semiconductor device of claim 1, wherein the switching element includes:
an electron transport layer, made of a first nitride semiconductor;
an electron supply layer, disposed on the electron transport layer and made of a second nitride semiconductor having a larger band gap than that of the first nitride semiconductor;
a gate layer, disposed on a portion of the electron supply layer and made of a third nitride semiconductor containing acceptor-type impurities;
the gate electrode, disposed on the gate layer; and
the source electrode and the drain electrode, in contact with the electron supply layer.

13. The nitride semiconductor device of claim 2, wherein
the switching element is disposed in an active region,
the first pad, the second pad, the capacitive element and the resistive element are arranged in a peripheral region surrounding the active region in a plan view, and
the electrode layer is disposed on an outer peripheral portion formed of a nitride semiconductor in the peripheral region.

14. The nitride semiconductor device of claim 2, wherein the electrode layer is made of a material same as a material of the gate electrode.

15. The nitride semiconductor device of claim 2, wherein the electrode layer is made of a material same as a material of the source electrode and a material of the drain electrode.

16. The nitride semiconductor device of claim 2, wherein the electrode layer is formed of at least one of Cu, Al, AlSiCu, AlCu, W, Ti and TiN.

17. A nitride semiconductor module, comprising:
the nitride semiconductor device of claim 1;
a source lead, a drain lead and a gate lead;
a source wire, connecting the source lead to the source pad;
a drain wire, connecting the drain lead to the drain pad;
a gate wire, connecting the gate lead to the gate pad; and
a first wire, connecting the second pad to the drain lead.

18. A nitride semiconductor module, comprising:
the nitride semiconductor device of claim 1;
a source lead, a drain lead and a gate lead,
a source wire, connecting the source lead to the source pad;
a drain wire, connecting the drain lead to the drain pad;
a gate wire, connecting the gate lead to the gate pad; and
a second wire, connecting the first pad to the drain lead.

19. A nitride semiconductor module, comprising:
the nitride semiconductor device of claim 1; and
a mounting board, on which the nitride semiconductor device is flip-chip mounted, wherein the mounting board includes:
a source connecting portion, connected to the source pad;
a drain connecting portion, connected to the drain pad;
a gate connecting portion, connected to the gate pad; and
a first connecting extension portion, extending from the drain connecting portion and connecting the second pad to the drain pad.

20. A nitride semiconductor module, comprising:
the nitride semiconductor device of claim 1; and
a mounting board, on which the nitride semiconductor device is flip-chip mounted, wherein the mounting board includes:
a source connecting portion, connected to the source pad;
a drain connecting portion, connected to the drain pad;
a gate connecting portion, connected to the gate pad; and
a second connecting extension portion, extending from the drain connection portion and connecting the first pad to the drain pad.
